(19) United States
(12) Patent Application Publication
(10) Pub. No.: US 2004/0018647 A1
(43) Pub. Date: Jan. 29, 2004

(54) Method for controlling the extent of notch or undercut in an etched profile using optical reflectometry

(75) Inventors: Steven J. Jones, Sunnyvale, CA (US); Shashank C. Deshmukh, San Jose, CA (US); Matthew F. Davis, Brookdale, CA (US); Lei Lian, Santa Clara, CA (US); Chan-Syun Yang, San Jose, CA (US)

Correspondence Address: Patent Counsel, Applied Materials, Inc., 3050 Bowers Avenue, P.O. Box 450A, Santa Clara, CA, 95052, US

(73) Assignee: Applied Materials, Inc.

(21) Appl. No.: 10/374,464

(22) Filed: Feb. 24, 2003

Related U.S. Application Data
(60) Provisional application No. 60/393,154, filed on Jul. 2, 2002.

(51) Int. Cl. H01L 21/336; H01L 21/00

(52) U.S. Cl. 438/8

(57) ABSTRACT

A method and apparatus for controlling lateral etching during an etching process. The method and apparatus includes laterally etching a lower layer of a stack of layers in a processing chamber, where an endpoint detection system radiates a spectrum of light over the lower layer being etched and an area over the stack of layers proximate to the lower layer being etched. The intensity of light reflected from at least one of the stacked layers positioned lateral to the lower layer being etched is then measured. An endpoint detection system terminates the etching process upon measuring a predetermined metric associated with the intensity of reflected light from the at least one of the stacked layers.

### CROSS REFERENCE TO RELATED APPLICATION

This patent application claims the benefit of U.S. Provisional Application, U.S. Ser. No. 60/393,154, filed Jul. 2, 2002, the contents of which are incorporated by reference herein in its entirety.

### FIELD OF THE INVENTION

Embodiments of the invention generally relate to semiconductor processing, and more particularly, to optical endpoint detection during semiconductor manufacturing processes.

### BACKGROUND OF THE INVENTION

The manufacture of miniature devices such as integrated circuits (ICs) and other devices formed on a substrate usually requires etching of dielectric material during the manufacturing process steps. During a plasma-enhanced process, such as an isotropic etch process, material on the wafer is removed in specific areas to subsequently form the components/features of the devices on the wafer. Isotropic etching may be used to create features that require undercut etch profiles, notched gates, isotropic poly etches that grow a hole having a critical dimension, and the like. In particular, lateral etching occurs under a mask (e.g., a photoresist mask) that is disposed over areas of the wafer that are to be protected from the etching process.

For example, increasing the operational speed of a field-effect transistor (FET) may be provided by reducing the cross-section area (i.e., channel width) of the channel between the source and drain of the FET. Decreasing the width of the channel requires a commensurate decrease in the width of the bottom surface of the gate. The upper surface of the gate should be large enough to allow for metalization and connectivity of the gate to the wiring layers of the integrated circuitry formed on the wafer, however, the width of the bottom surface may be decreased by notching the gate using the lateral etch process. Consequently, the gate structure with a narrower channel and greater operational speed may be fabricated.

Lateral etching may also be used during the formation of an undercut such as in a via (contact hole). In particular, the undercut is provided to reduce a likelihood of a conductive short occurring between a silicon layer and an oxide (e.g., TEOS) layer. For example, where a via is being formed in a stack of layers comprising silicon, an oxide such as TEOS, and a silicon nitride layer therebetween, performing an isotropic etch produces a profile where the silicon profile is offset from the silicon nitride layer. By contrast, simply performing and ansiotropic etch process at the final critical dimension, without an isotropic step, does not provide the offset, which increases the possibility of a conductive short between the silicon and the oxide.

Accordingly, precise control of the feature size (i.e., notch or undercut) is crucial in semiconductor device fabrication. Removing too much material or conversely, not removing enough material, may degrade performance or even cause the device to become non-operational. Various endpoint detection techniques have been utilized to monitor the progress of the process and/or to control the process such as by automatically terminating the specific processing operation being monitored. Moreover, the endpoint detection system must be consistent to provide repeatable and controlled performance, wafer-to-wafer and lot-to-lot, in terms of the amount of material removed during the etch process. In instances where an undercut under the mask is the desired feature, then the lateral distance of the undercut is the specific feature that is monitored by the endpoint detection system.

One endpoint technique includes monitoring the etch by-products (species) that form in the processing chamber during the etch process. Specifically, optical spectrometry has been used to monitor concentrations of the ionized species in the effluent. Once the species concentration increases to some predetermined value, the etch process is terminated. However, conventional plasma emission monitoring techniques have been found to result in inconsistent wafer throughput due to the variations in rate etch caused by chamber conditions (e.g., newly cleaned to end-of-cycle).

Therefore, there is a need in the art for providing improved endpoint detection for controlling the formation of features on a semiconductor wafer.

### SUMMARY OF THE INVENTION

The present invention provides a method and apparatus for controlling lateral etching during an etching process. The method and apparatus includes laterally etching a lower layer of a stack of layers in a processing chamber. An endpoint detection system radiates a spectrum of light over the lower layer being etched, as well as an area over the stack of layers proximate to the lower layer being etched. The endpoint detection system measures the intensity of light reflected from at least one of the stacked layers positioned lateral to the lower layer being etched and terminates the etching process upon measuring a predetermined metric associated with the intensity of reflected light from the at least one of the stacked layers.

### BRIEF DESCRIPTION OF THE DRAWINGS

So that the manner in which the above recited features of the invention are attained can be understood in detail, a more particular description of the invention, briefly summarized above, may be had by reference to the embodiments thereof, which are illustrated in the appended drawings. It is to be noted, however, that the appended drawings illustrate only typical embodiments of this invention, and are therefore, not to be considered limiting of its scope, for the invention may admit to other equally effective embodiments.

FIG. 1 depicts a flow diagram of a method for providing endpoint detection during the formation of a feature having lateral critical dimensions;

FIG. 2 depicts a cross-sectional view of a stack of layers having an exemplary feature with critical lateral dimensions being formed in the stack of layers;

FIG. 3 depicts an expanded cross-sectional view of the stack of layers 200 of FIG. 2;

FIG. 4 depicts a cross-sectional view of an exemplary enhanced plasma chamber system having an endpoint detection system used in accordance with the present invention;

FIGS. 5A-5C depict a series of graphs illustrating intensity changes of selective wavelengths of reflected light;

FIG. 6 depicts a graph of an exemplary reflectivity trace during an isotropic etch process;

FIG. 7 depicts a cross-sectional view of an exemplary transistor device having a gate structure undergoing a first embodiment of endpoint detection according to the present invention; and

FIGS. 8A and 8B depict cross-sectional views of an exemplary transistor device having a gate structure undergoing a second embodiment of endpoint detection according to the present invention.

To facilitate understanding, identical reference numerals have been used, where possible, to designate identical elements that are common to the figures.

### DETAILED DESCRIPTION

The present invention provides a method and apparatus for performing endpoint detection of an undercut formed in a stack of layers on a substrate, or a notch formed on a gate. In particular, light is radiated towards a laterally etched feature (e.g., undercut or notch), as well as an area of the stack of layers surrounding the particular feature. The radiated light comprises a broad spectrum of wavelengths that are absorbed by some layers, transmitted by some layers, and reflected by some layers. The endpoint detection system selectively detects one or more wavelengths reflected from a layer positioned lateral to the particular feature, such that the intensity of the detected wavelengths is measured. The measured intensity may then be used as a metric for determining the endpoint.

In one embodiment, the endpoint is determined by comparing the measured intensity of the reflected light to a predetermined intensity value representing an endpoint. Once the measured intensity equals the predetermined intensity value, the endpoint detection system ceases the etching process. In a second embodiment, the intensity of the detected wavelengths is measured periodically such that an etching rate of the feature may be computed. Once the etch rate is computed, the endpoint detection system terminates the etching process at a time associated with the amount of material in the layer that is removed to form a desired size of the feature.

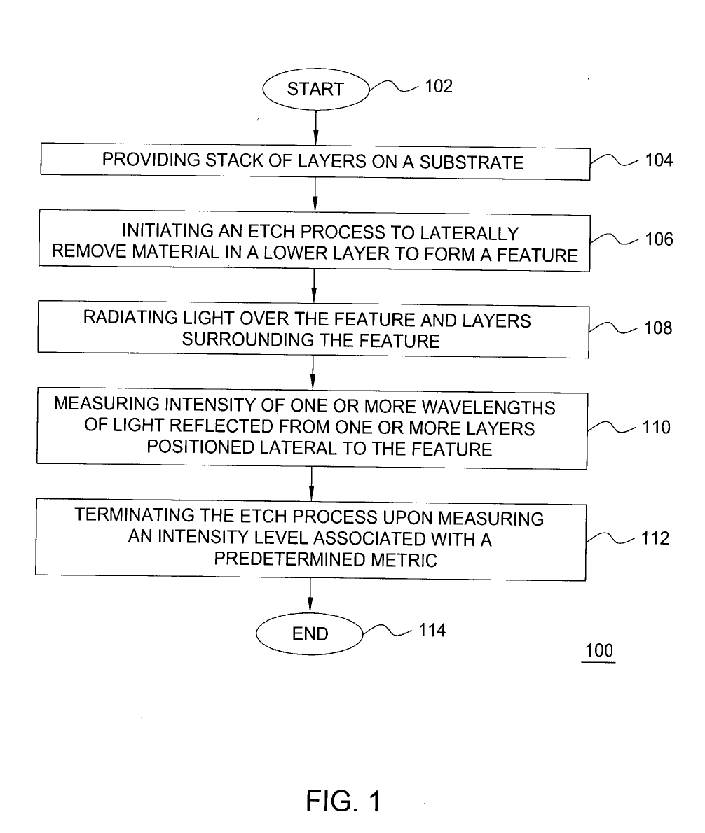

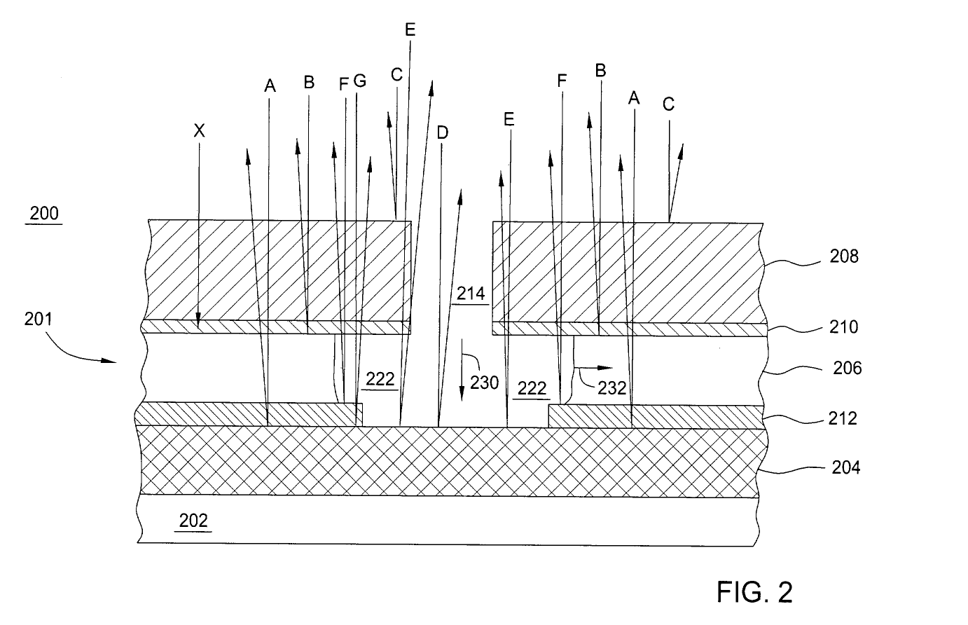

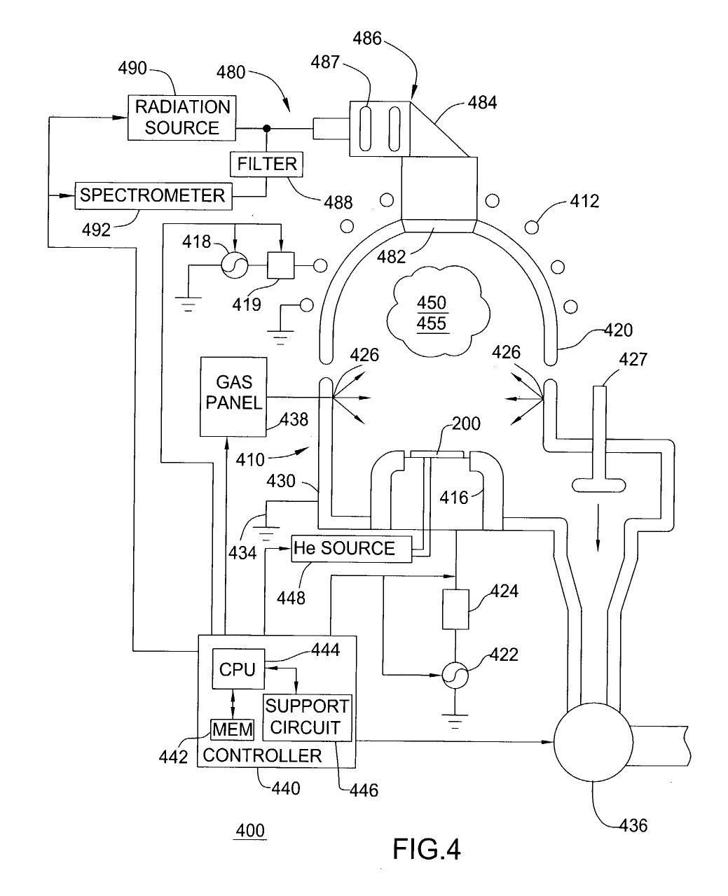

FIG. 1 depicts a flow diagram of a method 100 for providing endpoint detection during the formation of a feature having lateral critical dimensions. The method 100 is illustratively discussed in terms of forming an undercut feature beneath a photoresistive mask, as illustratively depicted in FIG. 2. An exemplary processing chamber for performing an etch process and having an endpoint detection system is illustratively depicted in FIG. 4. Endpoint detection is used to terminate the etch process when the lateral dimensions of the feature reaches a desired dimension (i.e., critical dimension). As such, the invention encompasses determining an endpoint for any feature that is being etched in a lateral direction.

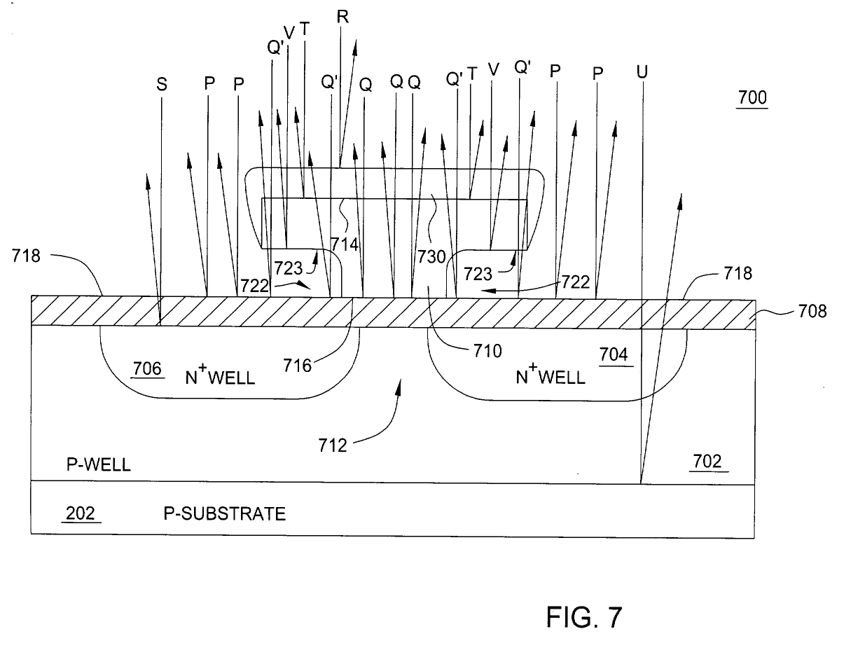

Method 100 starts at step 102 and proceeds to step 104, where a stack of layers is loaded into a processing chamber (e.g., processing chamber of FIG. 4 described below) for undergoing an etch process. At step 106, the etch process is initiated to form various features in the layers, such as laterally removing material in a lower layer of the stack to form an undercut (e.g., see FIG. 2), or a notch in a gate of a transistor (see FIG. 7). At step 108, a broad wavelength spectrum of light is radiated over the region where the feature is being etched, as well as the layers surrounding the feature being formed. At step 110, the endpoint detection system measures the intensity of one or more wavelengths of light respectively reflected from one or more layers positioned laterally to the feature. At step 112, the endpoint detection system terminates the etch process upon measuring an intensity level associated with a predetermined metric defining the endpoint, and at step 114, the method 100 ends.

FIG. 2 depicts a cross-sectional view of a stack of layers 200 having an exemplary feature 222 with critical lateral dimensions being formed in the stack of layers 200. For a better understanding of the invention, the reader should to view FIGS. 1 and 2 together.

At step 104, a substrate 202 having a plurality of conductive and insulative layers 201 forming the stack of layers 200 is loaded in a chamber for undergoing an etching process. The stack of layers 200 collectively provide the materials used to form components and features illustratively found in an integrated circuit (IC), such as transistors, capacitors, resistors, among others. In the exemplary embodiment depicted in FIG. 2, the stack 200 comprises a silicon substrate 202, an insulative oxide 204, such as tetraethylorthosilicate (TEOS), formed over the silicon substrate 202. A nitride layer 212, such as silicon nitride, is disposed over the oxide layer 204, and a conductive polysilicon layer 206 having a particular doping level is formed over the nitride layer 212. The nitride layer 212 serves as a barrier layer to prevent diffusion between the polysilicon layer 206 and TEOS layer 204.

A mask, such as a photo-resist layer 208, is formed over the area of the silicon layer 206 that is to be protected during the etching process. Alternatively, the mask may be a hard mask comprising inorganic amorphous carbon, silicon dioxide, among others. The photo-resist layer 208 generally comprises organic polymers, such as phenolformaldehyde, polyisoprene, polymethyl methacrylate, among others, which is well known in the art. Further, an optional backside anti-reflective coating (BARC) 210 is formed between the photo-resist mask 208 and the polysilicon layer 206. The anti-reflective coating is used to prevent unwanted reflections from the wafer surface. The number and composition of the layers formed on the substrate 202 are shown and discussed for illustrative purposes only, and are not to be considered as limiting.

At step 106, an etching process, such as ansiotropic or isotropic etch process, is performed to remove unwanted materials from the layers in order to define specific features of the component. The photo-resist layer 208 covers only those areas of the polysilicon layer 206 that are to be protected during an etching process. Gap 214 signifies a region of the polysilicon layer 206 that is exposed for the etching process. For example, as shown in FIG. 2, a via (hole) may be etched through the layers 201 (i.e., layers 206 and 212). FIG. 2 also depicts an undercut feature 222 formed in the polysilicon layer 206, which is formed during an isotropic etch process. The isotropic etch process comprises horizontal and vertical etch rates which are equal, thereby forming the undercut in the lateral direction, as shown by arrow 232.

In one embodiment, a contact hole may be provided by initially forming a via using an ansiotropic etching process, and then providing an isotropic etch process to form an undercut feature. The purpose of the undercut is to reduce a likelihood of a conductive short occurring between a silicon layer and an oxide (e.g., TEOS) layer. For example, where a via is being formed in a stack of layers comprising the silicon 2066, the oxide layer 204, and the silicon nitride layer 212 therebetween as shown in FIG. 2, performing an isotropic etch produces a profile where the silicon layer profile 206 is offset from the silicon nitride layer profile 212. By contrast, simply performing and ansiotropical etch process at the final critical dimension, without an isotropic step, does not provide the offset, which increases the possibility of a conductive short between the silicon profile 206 and the oxide 204.

An ansiotropic etching process removes material substantially orthogonal to the layers, as shown by arrow 230. The ansiotropic etching process has a horizontal etch rate that is much less than the vertical etch rate, thereby allowing for the formation of a via in the polysilicon layer 206. Endpoint detection during the ansiotropic etch phase is performed by using conventional optical endpoint detection of sampling the wavelengths of light emitted from the etch plasma. Specifically, a wavelength that corresponds to a species that is either created or removed during the ansiotropic etch process is selected for monitoring. Once the nitride layer 212 is removed, a slight recess is formed in the TEOS 204, thereby forming the contact via. After the ansiotropic etch process is complete, an isotropic etch process is used to subsequently form the undercut 222. Alternatively, the entire via and undercut feature (i.e., contact hole) may be provided by using only the isotropic etch process.

At step 108, during the isotropic etching process initiated at step 106, an endpoint detection system 480 (see FIG. 4) radiates light over the feature 222 being formed, as well as the stack of layers 201 surrounding the feature (i.e., undercut) 222. In one embodiment, the light that is radiated comprises a broad range (spectrum) of light having wavelengths of about 200 nanometers (nm) to 800 nm. The radiated light (beam) is provided above the feature and surrounding layers such that the radiated beam is incident normal (i.e., substantially orthogonal) to the wafer 200. Depending on the material forming the layers and the wavelengths of the radiated light impinging thereon, the wavelengths of light may be absorbed, transmitted, or reflected by the layers. In this manner, the radiated light impinges the stacked layers from above the wafer 200, where selective wavelengths are transmitted or reflected by the layers as they traverse towards the substrate 202.

It is noted that a layer that absorbs a particular wavelength of light does not further transmit or reflect the light. Rather, the light is produces heat at the layer. A layer that transmits a particular wavelength propagates the light through the layer. That is, the layer is transparent to that particular wavelength of light. A layer that reflects a particular wavelength of light does not transmit or absorb the light. Rather, the light bounces off the layer such as light reflected from a mirror.

Referring to FIG. 2, radiated light having a plurality of wavelengths labeled A-G is illustratively shown impinging the individual layers circumscribing the feature (e.g., undercut) 222. The individual layers 208, 210, 206, 212, 204, and 202 reflect and/or transmit the radiated light, depending on the composition of the layer and the particular wavelength of light impinging thereon. Specifically, reflections result from the materials on opposite sides of the layers that have substantially different refractive indexes.

The following exemplary wavelengths shown as wavelengths A-G illustrate various scenarios that may occur. For example, radiated light having wavelength “A” passes through layers 208, 210, 206, and 212, but is reflected by the upper surface of layer 204. Radiated light having wavelength “B” passes through (i.e., transmitted through) layers 208 and 210, but is reflected by the upper surface of layer 206. Radiated light having wavelength “C” is reflected by the upper surface of layer 208. Radiated light having wavelength “D” passes through the feature 222, and is reflected by the upper surface of layer 204. Radiated light having wavelength “E” passes through layers 208 and 210, as well as the feature 222, but is reflected by the upper surface of layer 204. Radiated light having wavelength “F” passes through layers 208 and 210, as well as the feature 222, but is reflected by the upper surface of layer 212. Radiated light having wavelength “G” passes through layers 208 and 210, as well as the feature 222 and layer 212, but is reflected by the upper surface of layer 204. It is noted that other wavelengths of light (not shown) are transmitted and absorbed by the layers. For example, a particular wavelength “X” may be transmitted through the photoresist layer 208 and absorbed by the BARC 210. However, such absorbed wavelengths are not significant to the invention, and are only mentioned for sake of completeness to better understanding the invention.

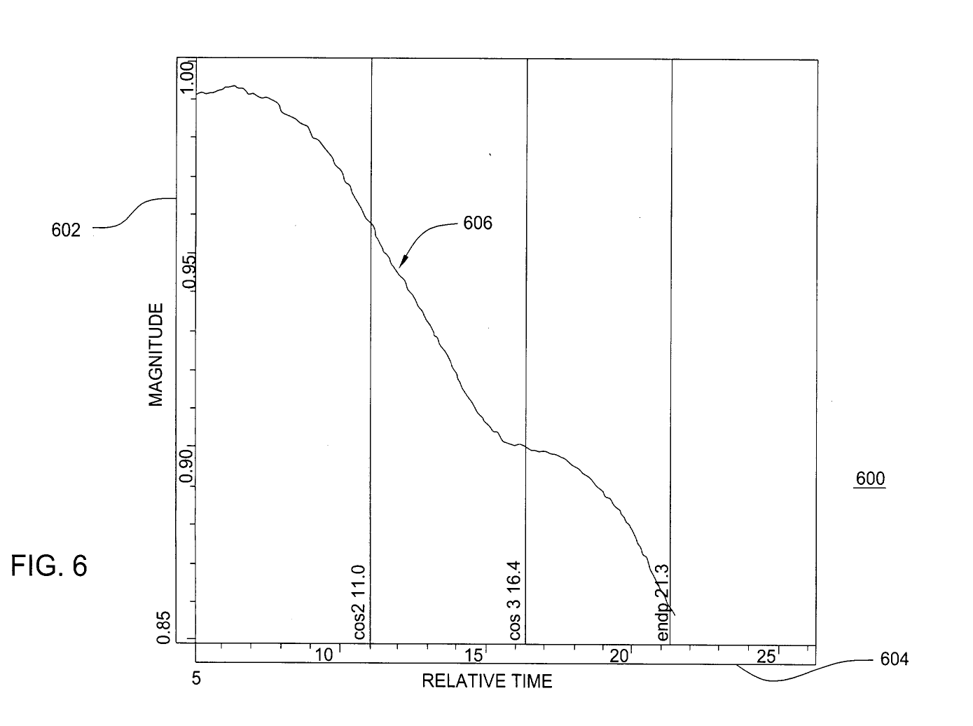

At step 110 of method 100, the endpoint detection system selectively measures the intensity of one or more wavelengths of light (e.g., wavelength B) reflected from one or more layers, such as layer the polysilicon layer 206. In particular, as the polysilicon is isotropically etched, the undercut 222 is formed under the photoresist 208. Light having a particular wavelength is reflected from the upper surface of the remaining polysilicon layer 206 and transmitted through the photoresist layer 208. Such reflected light is selected for monitoring. The selected wavelength or wavelengths typically are about 700-800 nanometers, which are able to pass through the photoresist layer 208. This reflected light is then collected and its intensity is used to trigger the endpoint. As the isotropic etch progresses, the surface area of the polysilicon layer 206 diminishes laterally, which correspondingly reduces the amount of light reflected from the polysilicon surface. Therefore, a reflective endpoint trace (see curve 606 of FIG. 6) diminishes over time as the critical dimension of the undercut (or notch) grows. As such, the measured intensity may be used as a metric for determining the endpoint of the etch process. For example, changes in intensity measurements may be associated with an etch rate, which may be used to predict the endpoint of the etch process.

Recall, that in the conventional endpoint detection systems, the light is sampled from the etch plasma, and a wavelength is selected corresponding to a species that is created or removed from a film during the etching process. However, such conventional endpoint detection system does not work during a lateral etch process, since there is no etch species change occurring during the isotropic etch process. As such, the inventive endpoint detection system described herein overcomes this deficiency of the conventional endpoint detection systems.

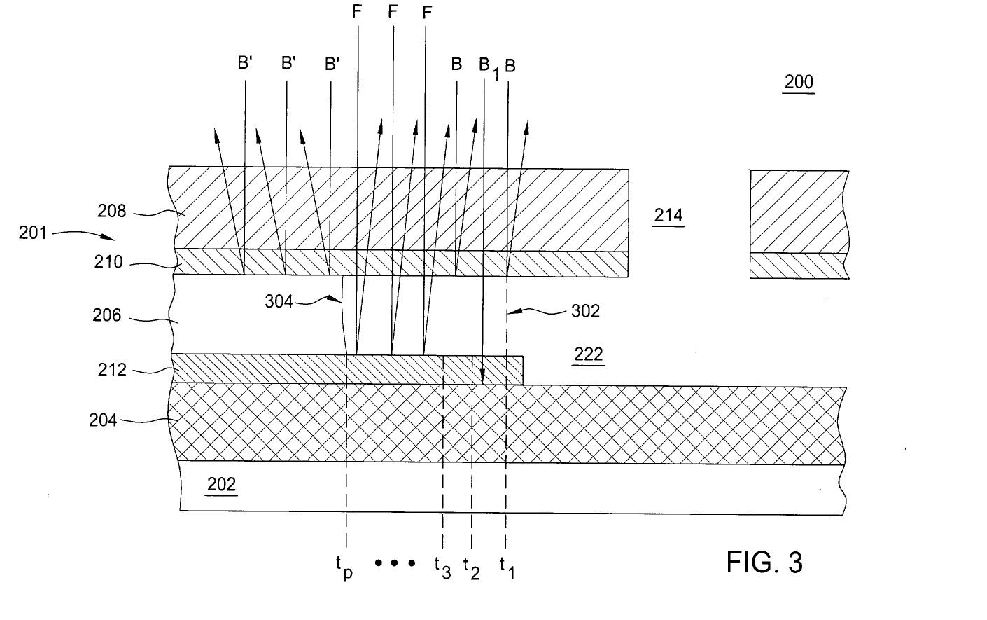

FIG. 3 depicts an expanded cross-sectional view of the stack of layers 200 of FIG. 2. Specifically, FIG. 3 is an enlarged depiction of the left portion of the cross-section shown in FIG. 2. Further, FIG. 3 depicts two exemplary wavelengths of light (i.e., wavelengths B and F) being reflected from particular layers surrounding the feature (undercut) 222.

It is noted that the isotropic etch process removes the material from the layer 206 uniformly, and in particular, 360 degrees in the lateral direction. However, for purposes of understanding the invention, the polysilicon layer 206 is shown only being removed during the etch process from the left side of the undercut 222 being formed. Accordingly, at time t1, the layer 206 has been laterally etched to the position indicated at 302. Subsequently, at time tₚ, the layer 206 has been laterally etched to the position indicated at 304.

At time t1, the portion of the spectrum of radiated light having a wavelength B transmits through layers 208 and 210, and is reflected from the upper surface of layer 206. It is noted that the radiated light at wavelength B also includes the wavelengths also shown as B′, which have the same wavelength. Specifically, as the etch process progresses, more material from layer 206 is removed, which thereby reduces the amount of light having a wavelength B being reflected from layer 206. At time tp, only the wavelengths designated B′ are reflected from layer 206. As such, the intensity of light for wavelength B decreases during the etch process, since there is less of layer 206 that reflects the light at wavelength B.

It is noted that as the polysilicon material is progressively removed, the wavelengths of light designated as B (and not B′) pass through the undercut feature in the vacuum environment of the processing chamber, and may either be absorbed, transmitted, or reflected by some other layer below the undercut 222. For example, the wavelength designated “B₁”, which has the same wavelength of B and B′, transmits through both the vacuum environment at the feature 222 and the barrier layer 212, and is finally absorbed by the oxide layer 204. One skilled in the art will appreciate that the exemplary wavelength B₁ may be absorbed, transmitted, and/or reflected by the layers below the feature in any number of ways.

Additionally, radiated light having an exemplary wavelength F passes through layers 208 and 210, as well as the feature 222, and is reflected from the upper surface of layer 212. In one embodiment, the polysilicon layer 206 absorbs wavelength F. In one embodiment, as the etch process progresses and the silicon layer 206 is removed, wavelength F passes through the feature 222 and is reflected from the surface of the nitride layer 212 such that the intensity of reflected light for wavelength F increases.

In an alternate embodiment, wavelength F may be attenuated by the polysilicon layer 206. That is, wavelength F is transmitted through the polysilicon layer 206, but at a lower energy level prior to being reflected at the surface of the nitride layer 212. In this instance, the intensity of reflective wavelength F is low as compared to when the polysilicon is removed during the etch process. In particular, once the polysilicon is removed, wavelength F passes through the feature 222 and the intensity of the reflected wavelength increases, due to the absence of the attenuating polysilicon material. It is noted that the intensities of some of the wavelengths (e.g., wavelengths A, C, D, and E) will show very little change or no change at all, and in one embodiment, are not utilized for determining an endpoint.

At step 112 of method 100, the etch process is terminated upon measuring an intensity level associated with a predetermined metric. In one embodiment, the predetermined metric comprises the magnitude of the intensity of a particular wavelength of reflected light. Specifically, the predetermined intensity value of the reflected light of wavelength B represents a particular critical dimension of a feature. Once the measured intensity equals the predetermined intensity metric, the desired critical dimension of that feature has been formed, and the etch process is terminated. Referring to FIG. 3, if the measured intensity at time tₚ equals the predetermined intensity (i.e., where the only reflected light from layer 206 comes from wavelengths designated B′), then the etch process is terminated.

Alternatively, the intensity of reflected light illustratively having a wavelength F may also be measured and compared to a predetermined value for determining when the etch process should be terminated. As discussed above, the intensities of more than one wavelength may be utilized during endpoint detection. Measuring intensities of additional wavelengths of the reflected light and comparing the desired value to the predetermined value provides greater accuracy in the overall determination of the amount of unwanted materials that have been removed, and hence, greater precision in determining the endpoint of the etch process.

The present invention measures the intensities of particular wavelengths of light reflected from layers that are positioned lateral to the feature 222 being formed. That is, the measurements may be performed on the material that is itself being removed (e.g., layer 206), or some other layer that is laterally positioned from the layer being removed (e.g., layer 212). For example, the intensity of reflected wavelength F is only measurable after portions of layer 206 have been removed. In this instance, the reflected wavelength F occurs lateral to the remaining portion of layer 206. One skilled in the art will appreciate that other reflected wavelengths from other lateral layers may also be detected and measured to determine an endpoint.

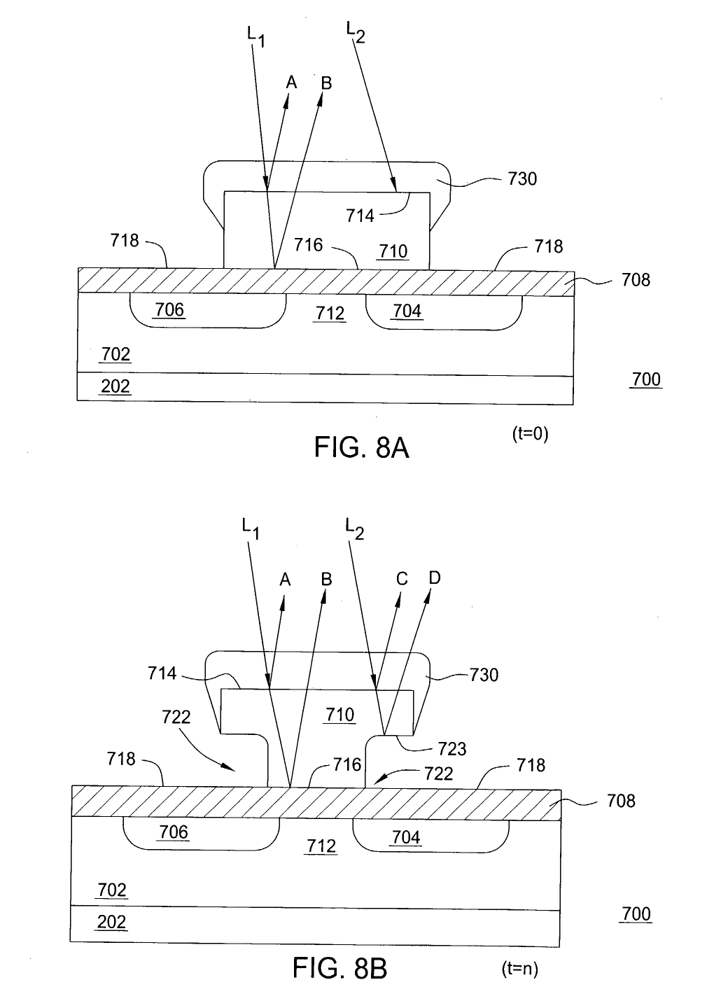

Endpoint detection according to the present invention may be measured by employing different techniques having differing sensitivities. FIGS. 7, 8A, and 8B depict cross-sectional views of an exemplary transistor device 700 having a gate structure 710 formed by a lateral notch 722, where the different endpoint detection techniques may be illustrated. A first technique employs the method shown and described above regarding FIGS. 2 and 3. A second endpoint detection technique is discussed below with regard to FIGS. 8A and 8B.

FIG. 7 depicts a cross-sectional view of an exemplary transistor device 700 having a gate structure 710 undergoing a first embodiment of endpoint detection according to the present invention. For example, FIG. 7 may illustratively represent a gate structure 710 of a CMOS transistor 700. The exemplary transistor 700 is formed on a wafer 702 (e.g., a P-substrate) and comprises a doped well (e.g., P-well 702) having high doped (e.g., by boron (B) or arsenic (As)) wells 708 and 710, which are separated by a channel 712.

An electrode (gate region) 710 is patterned for positioning over the channel 712 and portions of the wells 704 and 706. The electrode 710 is generally formed from polysilicon (Si) to a thickness of about 100 to 200 nm. A thin dielectric layer 708 (e.g., a silicon dioxide (SiO₂) layer) is disposed between a bottom surface 716 of the polysilicon electrode 710 and an upper surface of the channel 712 and respective portions of the doped well 702, highly doped wells 704 and 706. Optionally, the dielectric layer 708 may cover the entire surface area over the highly doped wells 704 and 706 and the doped will 702, as illustratively shown in FIG. 7. As such, the electrode 710 is disposed on an upper surface 718 of the oxide layer 708 over the channel 712.

It is noted that operational speed of the transistor 700 increases when the width of the channel 712 is decreased. Decreasing the width of the channel 712 requires a commensurate decrease in the width of the bottom surface 716 of the electrode 710. An upper surface 714 of the electrode 710 should be large enough to allow for metallization and connectivity of the electrode 710 to the wiring layers of the integrated circuitry formed on the substrate 202, however, the width of the bottom surface 716 may be decreased by notching the electrode 712 using the lateral etch process of the present invention.

A protective mask 730 is disposed upon the electrode 710 using, for example, a plasma deposition process. The mask 730 thins towards the dielectric layer 708 and has a minimal width proximate the intersection between the dielectric layer 708 and the bottom surface 716 of the gate 710. As such, the mask 730 protects the upper portion of the sidewalls and the upper surface 714 of the electrode 710 and leaves an area near the bottom surface 716 exposed to the etchant plasma during the lateral etch process. Accordingly, method 100 may be performed as discussed above on the exemplary transistor device 700 to provide the notch 722 in the gate 710 at the exposed area near the bottom surface 716 of the gate 710.

Endpoint detection is provided during the formation of the notch 722 in the gate 710 in a similar manner as described above with regard to the undercut 222 formed in the stack of layers 201. The following exemplary wavelengths shown as wavelengths P-V illustrate various scenarios that may occur. For example, radiated light having wavelength “P” is absorbed by the mask 730, but is reflected by upper surface of layer 708. Radiated light having wavelength “Q” passes through (i.e., transmitted through) the mask 708 and polysilicon gate 710, but is reflected by the upper surface 718 of layer 708. Radiated light having wavelength “R” is reflected by the upper surface of the mask 710. Radiated light having wavelength “S” passes through the layer 708, and is reflected by the upper surface of the well 702. Radiated light having wavelength “T” passes through the mask 710, but is reflected by the upper surface 714 of layer 710. Radiated light having wavelength “U” passes through layers 708 and 702, but is reflected by the upper surface of layer 202. Radiated light having wavelength “V” passes through layers 730 and a portion of layer 710, and is reflected by a transition area 723 where notch 722 is formed, i.e., the transition at the upper undercut surface area of the electrode 710 and the vacuum environment formed at the notch 722. It is noted that other wavelengths of light (not shown) are transmitted and absorbed by the layers. However, such absorbed wavelengths are not significant to the invention, and are only mentioned for sake of completeness to better understanding the invention.

The present invention measures the intensities of selected (i.e., filtered) wavelengths of light reflected from layers that are positioned lateral to the feature (e.g., notch) 722 being formed. That is, the measurements may be performed on the material that is itself being removed (e.g., polysilicon gate 710), or some other layer that is laterally positioned from the layer being removed (e.g., layer 708).

For example, selected wavelength Q may be attenuated as it passes through the polysilicon gate 710 before being reflected by layer 708. While the notch 722 is being formed during the etching process, less of the wavelength Q is attenuated, since some of the polysilicon material has been etched away to form the notch 722. The wavelength Q′ represents the same wavelength Q, but illustrates a later time during the etch process when the wavelength passes through the mask 730, polysilicon 710, and the feature (notch) 722, prior to being reflected from layer 708.

As such, the intensity of the selected wavelength Q increases, since the attenuating affects of the polysilicon layer 710 diminish as the polysilicon 710 is removed. In other words, there is less polysilicon available as the etch process progresses to attenuate the wavelength Q. Therefore, the intensity of wavelength Q increases as the etch process progresses. One skilled in the art will appreciate that other reflected wavelengths from other lateral layers may also be detected and measured to determine an endpoint. Once the measured intensity equals a predetermined intensity, which represents a critical dimension of the notch 722, the etch process is terminated.

Alternatively, the intensity of wavelength “V” may be measured as the notch 722 is formed. Recall, that radiated light having wavelength “V” passes through layers 730 and a portion of layer 710, and is reflected by the transition area 723 where the notch 722 is being formed. Specifically, the isotropic etching forms the lower notch portion 723, which defines the upper surface area of the notch 722. Once the measured intensity of wavelength “V” equals a predetermined intensity that represents a critical dimension of the notch 722, the etch process is terminated.

FIGS. 8A and 8B depict cross-sectional views of an exemplary transistor device 700 having a gate structure undergoing a second embodiment for providing endpoint detection according to the present invention. The structures depicted in FIGS. 8A and 8B are the same as shown and described regarding FIG. 7. FIG. 8A depicts the transistor prior to beginning the isotropic etch process, and FIG. 8B depicts the transistor after the isotropic etch process has begun. It is noted that the second technique provides greater sensitivity for measuring a critical dimension of the feature than the first endpoint technique described above.

Referring to FIG. 8A, the polysilicon layer 710 is shown formed over the channel 712 and portions of the high-doped well regions 704 and 706 prior to commencing the isotropic etch process. A particular wavelength of light “L₁” is selected to measure the intensity of reconstructed (i.e., in-phase) reflections from different transition areas. In particular, a wavelength L₁ is selected to exhibit the characteristics where a portion of the radiated light L₁ reflects from the upper surface 714 of the polysilicon layer 710 (e.g., shown by arrow “A”), while another portion propagates through the polysilicon layer 710 and is subsequently reflected from the upper surface 714 of the oxide layer 708 (e.g., shown by arrow “B”).

The endpoint detection system measures the intensity of the reconstructed (in-phase) reflections over time. For the notched gate illustratively being formed in FIGS. 8A and 8B, the selected wavelength L₁ is radiated over the entire polysilicon layer 710. Prior to forming the notch 722 at a time t=0, the measured intensity of the reconstructed (in-phase) reflections “A” and “B” for the particular wavelength L₁ will be maximized as shown in FIG. 8A. As the notch 722 is being formed during the isotropic etch process (at time t=n, where n is a positive number), the intensity of the in-phase reflections “A” and “B” decreases as material is removed, as shown in FIG. 8B.

Similarly, the endpoint detection system is able to measure the intensity of deconstructed (out-of-phase) reflections over time. Referring to FIG. 8B, wavelength L₂ may be selected to exhibit out-of phase reflection characteristics where a portion of the radiated light L₂ reflects from the upper surface 714 of the polysilicon layer 710 (e.g., shown by arrow “C”), while another portion propagates through the polysilicon layer 710 and is subsequently reflected from the transition to the vacuum environment 723 (e.g., shown by arrow “D”). In this instance, the endpoint detection system measures the intensity of the deconstructed (out-of-phase) reflections “C” and “D” for selected wavelength L₂ over time. In FIG. 8A at time t=0, the selected wavelength L₂ is radiated over the entire polysilicon layer 710, where reflections “C” and “D” are out-of-phase and provide minimal reflection (“C” plus “D” approximately equals zero. In FIG. 8B, as time progresses (t=n) and more material is removed during the formation of notch 722, the intensity of out-of-phase reflections “C” and “D” increases. As such, the endpoint detection system may contemporaneously monitor in-phase reflections (“A” and “B”) and out-of-phase reflections (“C” and “D”), thereby increasing the sensitivity of the endpoint detection system over monitoring a single selected wavelength.

In a third embodiment, the endpoint detection system computes an etch rate that is used as a metric for determining the endpoint. The remaining embodiments are discussed primarily with regard to the undercut feature 222 discussed herein and shown in FIGS. 2 and 3. However, the teachings of the various embodiments discussed below are also applicable to the detection of an endpoint of the notch feature 710 discussed with regard to FIG. 7, or any other critical dimension feature that is formed by a lateral etch process (i.e., isotropic etch process).

As shown in FIG. 3, a snapshot of the intensity of a particular reflected wavelength (e.g., wavelength B) is illustratively taken at times t2 and t3. The difference in intensities between the times the snapshots were taken may be used to represent the amount of material removed during that time difference. That is, an etch rate may be formulated and used to determine when the etch process may be terminated at some future time.

For example, the intensity of the measured wavelength may be 0.95 at time t2 and 0.85 at time t3. The difference in intensity measurements at time t2 and time t3 may be associated with an etch rate. If the etch rate is illustratively determined to be 2 nanometers per second at time t3, and an additional 20 nanometers are desired to be laterally removed to form the undercut in layer 206, then the etch process will continue for another 10 seconds before being terminated. At step 114, method 100 ends.

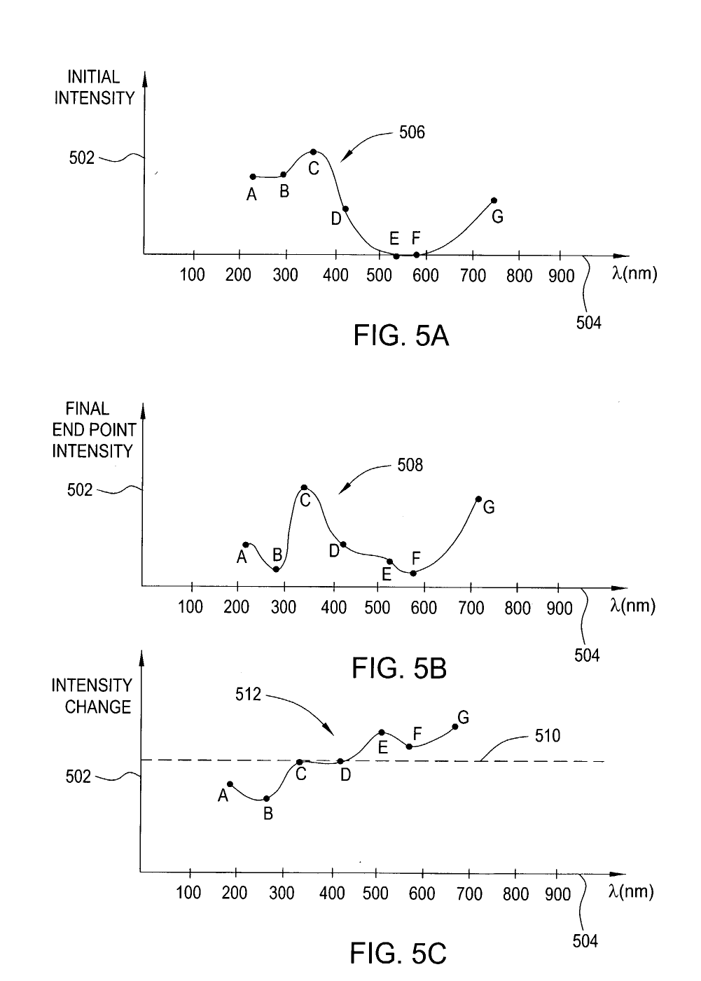

FIGS. 5A-5C depict a series of graphs illustrating intensity changes of selective wavelengths of reflected light. A ratio of the intensity of each wavelength at the endpoint over the beginning of the etch process may be used in a third embodiment to provide endpoint detection. FIG. 2 should be viewed along with FIGS. 5A-5C. Referring to FIG. 2, for purposes of understanding the invention, reflected wavelength “A” illustratively has the lowest value (e.g., 240 nm), while wavelengths B-G progressively increase. For example, wavelength B is illustratively 287 nm, wavelength C is illustratively 356 nm, and so forth up to wavelength G, which is illustratively 734 nm. It is noted that the reflected wavelengths depend upon the type of material from which the light impinges, and the above example (wavelengths A to G in a progressive order and lengths) is provided for illustrative purposes only.

Referring to FIG. 5A, the y-axis 502 represents a known initial intensity for each of the wavelengths A-G shown on the x-axis, prior to the formation of the undercut. The initial intensities may be provided by empirical data, or by impinging the light on the stack of layers prior to the beginning of the etch process. Where a feature includes an undercut 222 is being formed, the via may already be formed prior to performing the initial intensity measurements. That is, the initial intensity measurements may be made with the via already being formed. Curve 506 represents the exemplary initial intensity measurements at wavelengths A-G for the stack of layers shown in FIG. 2.

Referring to FIG. 5B, curve 508 represents the exemplary final intensity levels at wavelengths A-G, where the undercut 222 has been formed in the stack of layers shown in FIG. 2. That is, curve 508 represents the intensity levels of the particular wavelengths A-G after the desired endpoint has been reached. The final intensity curve 508 is provided by empirical data. Referring also to FIG. 2, it is noted that the final intensities of wavelengths A and B decreased due to the reduction of the reflective layers 206 and 212. The intensities of wavelengths E and F increased from zero to some positive intensity value, while wavelength G also increased due to the reflection through layer 212 at layer 204. Further, the intensities of wavelengths C and D remained relatively constant, since the etch process does not remove any significant amounts of material related to these respective reflections.

FIG. 5C depicts a curve 512 that illustrates intensity change as a ratio between the final endpoint intensity and the initial intensity for each wavelength A-G. A ratio equal to one (1) is shown as occurring on axis 510. The endpoint detection system measures the illustrative intensities for the selected wavelengths (e.g., wavelengths A-G) during the etch process, and computes a measured ratio of the measured intensities against the initial intensities of FIG. 5A. The measured ratio wavelengths may be plotted in a similar manner as the desired curve 512 of FIG. 5C. Once the measured ratio curve matches the final desired ratio curve 512 of FIG. 5C, then the endpoint detection system terminates the etching process. As such, the endpoint detection system utilizes multiple reflections from various layers to determine the endpoint in a more precise manner.

FIG. 4 depicts a cross-sectional view of an exemplary enhanced plasma chamber system 400 having an endpoint detection system 480 used in accordance with the present invention. One type of plasma chamber system 400 that may be used to accomplish the method 100 of the present invention is a decoupled plasma source (DPS) II reactor system, which is an inductive plasma reactor that is commercially available from Applied Materials, Inc. of Santa Clara, Calif. Those skilled in the art will understand that other types of plasma chamber systems may be used to practice the invention. For example, capacitively coupled plasma chambers, such as an MxP+ dielectric etch chamber, a Producer Etch chamber, and the like, also commercially available from Applied Materials, Inc., as well as other forms of etch chambers, including chambers with remote plasma sources, microwave plasma chambers, electron cyclotron resonance (ECR) plasma chambers, and the like may also be utilized.

The exemplary enhanced plasma chamber system 400 shown in FIG. 4 is an inductive plasma chamber, such as the DPS-II reactor system. The plasma chamber system 400 comprises a processing chamber 410 having at least one inductive coil antenna segment 412 positioned exterior to a dielectric dome-shaped ceiling 420 (referred to herein as the dome 420). Other chambers may have other types of ceilings, e.g., a flat ceiling. The antenna segment 412 is coupled to a radio-frequency (RF) plasma source 418 that is generally capable of producing an RF signal having a tunable frequency of about 50 kHz and 13.56 MHz and has a power of 200 to 3000 Watts. The RF source 418 is coupled to the antenna 412 through a matching network 419. Process chamber 410 also includes a wafer support pedestal (cathode) 416 that is coupled to a biasing source 422 that is generally capable of producing an RF signal having a tunable frequency between 50 kHz and 13.56 MHz and a power between 0 and 500 Watts. The source 422 is coupled to the cathode 416 through a matching network 424. Optionally, the source 422 may be a DC or pulsed DC source. The chamber 410 also contains a conductive chamber wall 430 that is connected to an electrical ground 434. A controller 440 comprising a central processing unit (CPU) 444, a memory 442, and support circuits 446. The controller 440 is coupled to the various components of the etch process chamber 410 to facilitate control of the etch process.

In operation, a wafer 200 is placed on the wafer support pedestal 416 and gaseous components are supplied from a gas panel 438 to the process chamber 410 through entry ports 426 to form a gaseous mixture 450. The gaseous mixture 450 is ignited into plasma 455 in the process chamber 410 by applying RF power from the RF sources 418 and 422 respectively to the antenna coil 412 and the substrate support pedestal (cathode) 416.

Specifically, the inductive chamber 400 decouples ion density (ion flux) from ion energy by producing plasma via the inductive magnetic source 418 on top of the dielectric dome 420. That is, the RF power is coupled through the dielectric dome 420, rather than through an electrode. The power is coupled via RF magnetic fields (as opposed to electric fields) from RF current in the coil 412. These RF magnetic fields penetrate into the plasma and induce RF electric fields, which ionize and sustain the plasma 455. The cathode 416 is biased by the biasing source 422 to determine the ion acceleration energy towards the cathode 416. The inductive source 418 influences ion flux because the induced electric fields do not produce large sheath voltages, while the cathode biasing source 422 has negligible influence in determining ion flux, since most of the RF power is used for accelerating ions.

The pressure within the interior of the etch chamber 410 is controlled using the gas panel 438 and a throttle valve 427 situated between the chamber 410 and a vacuum pump 436. The temperature at the inner surface of the chamber walls 430 is controlled using liquid-containing conduits (not shown) that are located in the walls 430 of the chamber 410.

The temperature of the wafer 200 is controlled by stabilizing the temperature of the support pedestal 416 and flowing helium gas from source 448 to channels formed by the back of the wafer 200 and grooves (not shown) on the pedestal surface. The helium gas is used to facilitate heat transfer between the pedestal 416 and the wafer 200. During the processing, the wafer 200 is heated by a resistive heater within the pedestal to a steady state temperature, while the helium facilitates uniform heating of the wafer 200. Using thermal control of both the dome 420 and the pedestal 416, the wafer 200 is maintained at a temperature of between 10 and 500 degrees Celsius.

To facilitate control of the chamber 410 as described above, the controller 440 may be one of any form of general-purpose computer processor that can be used in an industrial setting for controlling various chambers and sub-processors. It is noted that one or more controllers 440 may be utilized to control the components of the system 400. The exemplary controller 440 comprises a processor (e.g., CPU) 444, memory 442, and support circuits 446.

The memory 442 is coupled to the CPU 444. The memory 442, or computer-readable medium, may be one or more of readily available memory such as random access memory (RAM), read only memory (ROM), floppy disk, hard disk, or any other form of digital storage, local or remote. The support circuits 446 are coupled to the CPU 444 for supporting the processor 444 in a conventional manner. These circuits include cache, power supplies, clock circuits, input/output circuitry and subsystems, and the like. Software routines that, when executed by the CPU 444, cause the reactor to perform processes of the present invention that are generally stored in the memory 442.

The software routines may also be stored and/or executed by a second CPU (not shown) that is remotely located from the hardware being controlled by the CPU 444. The software routines, when executed by the CPU 444, transform the general purpose computer into a specific purpose computer (controller) 440 that controls the chamber operation such that the lateral etch process and endpoint detection of method 100 is performed in accordance with method 100 of the present invention.

Although the present invention is discussed as being implemented as a software routine, some of the method steps that are disclosed therein may be performed in hardware as well as by the software controller. As such, the invention may be implemented in software as executed upon a computer system, in hardware as an application specific integrated circuit or other type of hardware implementation, or a combination of software and hardware.

In one embodiment, the endpoint detection system 480 is mounted over a window 482 formed in the lid 472, and is used to detect an endpoint of a stage of the process being performed on the substrate 202. The endpoint detection system 480 comprises a radiation source 490, a radiation detector (spectrometer) 492, and an optional lens assembly 486. One exemplary endpoint detection system 480 is an “EYE-D” interfermetric Endpoint detection system, manufactured by Verity Instruments Inc., of Carrollton, Tex., which is used in conjunction with the exemplary DPS II chamber 400. It is noted that the interfermetric endpoint detection system of the present invention may be used with other types of reactor systems as well.

In particular, the radiation source 490 provides radiation such as x-ray, ultraviolet, polychromatic (visible) light, or infrared radiation. The radiation source 490 can provide radiation having only a predominate wavelength, such as a monochromatic light having primary radiation at a single or a few wavelengths, for example, a He—Ne or Nd—YAG laser. Preferably, the radiation source 490 can provide multiple wavelengths of radiation, such as polychromatic light. Suitable radiation sources 490 for providing polychromatic light include Hg discharge lamps that generate a polychromatic spectrum of light having wavelengths in the range of about 200 to 800 nanometers, arc lamps such as xenon or Hg—Xe lamps, tungsten-halogen lamps, and light emitting diodes (LED), among others.

A filtering device 488 is provided to selectively remove undesirable wavelengths, such that the sensor 492 may detect particular wavelengths reflected from the layers of interest. In one embodiment, the filter 488 is positioned in front of the detector 492, but may be positioned in other locations, such as at the optical lens assembly 486. A suitable filter 488 comprises a stack of thin films on a transparent support that selectively transmits radiation having the desired wavelength or a lens made from a material that selectively passes radiation having the desired wavelength. The filter may also comprise a diffraction grating having a diffraction spacing that scatters radiation having undesirable wavelengths and allow radiation having the desired wavelength to pass through. Other suitable or equivalent filtering means may include, for example, attenuation of radiation though a long path length in partially absorbing material, or selective electronic filtering of the signal from the radiation detector 492 to read only the portion of the signal corresponding the radiation having the desired wavelength, among others.

The radiation detector 492 detects radiation reflected by the substrate 200. The radiation detector 492 comprises a radiation sensor (not shown), such as a photovoltaic cell, photodiode, charge coupled device (CCD), photomultiplier, or phototransistor, which provides an electrical output signal in response to a measured intensity of radiation. The signal may comprise a change in the level of a current passing through an electrical component, or a change in a voltage applied across an electrical component. A suitable system for coupling the radiation detector 492 to the chamber 402 comprises fiber-optic cable leading from the chamber 402 to the sensor of the radiation detector 492.

The optical lens assembly 486 is disposed over the window 482 formed in the chamber lid 472. The window 482 may be fabricated from quartz, sapphire, or any other transparent material that allows the radiation to impinge unimpeded onto the wafer 200. The optical lens assembly 486 optionally comprises at least one lens 487 and/or at least one reflective mirror 484. The at least one lens is used to focus radiation emitted by the radiation source 490 onto the substrate 200 and/or to focus radiation at least partially reflected from the layers on the substrate onto the sensor of the radiation detector 492.

For example, for a radiation source 490 comprising a Hg-discharge lamp located outside the chamber 402, as shown in FIG. 4, a plurality of convex lenses 487 can be used to focus radiation from the lamp through a window 482 disposed in the lid 472, and onto a beam spot on the substrate 200. The lenses 487 may also be used to focus reflected radiation onto the sensor of the radiation detector 492. Further, the mirror assembly 484 may be used to direct radiation emitted by the radiation source 490 onto the substrate 200, as well as reflected radiation back to the radiation detector 492.

In one exemplary embodiment, system 400 is used to perform an etch process on a stack of layers 201 similar to the exemplary embodiment shown and described by method 100 in FIGS. 1-3. One particular recipe used in conjunction with the endpoint detection system 480 illustratively provides an undercut having a radius of 200 nanometers formed in a polysilicon layer 206 having a thickness of about 500 angstroms.

In the illustrative embodiment shown in FIG. 2, the TEOS layer 204 has a thickness of about 2000 Angstroms, the nitride layer 212 has a thickness of about 50 Angstroms. The photo-resist mask is a 248 nm photoresist having a thickness of about 5000 Angstroms, while the BARC has a thickness of about 500 Angstroms. The polysilicon layer 206 has a thickness of about 500 Angstroms. One skilled in the art will appreciate that the thickness of each layer is dependent on the design specifications of the components and features being formed, and such dimensions should not be considered as limiting.

In particular, the substrate 200 is moved into an appropriate processing position over the substrate support pedestal 416 in the chamber 406. At step 104 of method 100, process gases comprising NF₃ and Cl₂ are introduced into the chamber 406. In the exemplary recipe, the NF₃ is supplied into the chamber 406 at a rate between about 0 to about 50 sccm, while the Cl₂ is supplied into the chamber 406 at a rate between about 0 to about 100 sccm. The flow ratio of NF₃ and Cl₂ is in a range of about (0-100):(50-0). The pressure in the chamber 406 is brought to a pressure between about 50 milliTorr and about 80 milliTorr by adjusting a pumping valve 427 to pump the gas to the desired pressure. In one specific embodiment, the NF₃ is supplied into the chamber 406 at a rate of about 7 sccm, while the Cl₂ is supplied into the chamber 406 at a rate of about 56 sccm. The flow ratio is about 1:8, and the chamber pressure is about 50 milliTorr.

Plasma 455 is generated via application of the source power by the power supply 418 to the antennas 412 and ground 434. The power supply 458 applies the source power between about 150 Watts and 400 Watts, at a frequency of about 12.56 MHz, which ignites the processing gases introduced into the processing region 450 into the plasma 455. The chucking power supply 434 is turned on to chuck the wafer 200 to the substrate support pedestal 416. The bias power supply 422 is activated and the substrate support (i.e., cathode electrode) 416 is biased with a bias signal. In particular, the RF bias power source 422 is turned on, and the cathode electrode 416 is biased to between about 15 Watts and about 50 Watts at a frequency of about 13.56 MHz. The etching process the wafer processing procedure (e.g., etching an undercut feature 222) is performed according to a particular recipe.

At step 110, the operation of the plasma process is monitored by the endpoint detection system 480 to determine when the undercut feature is fully formed, and the etching process may be terminated. In particular, a beam of polychromatic light having a wavelength spectrum between 200 and 800 nanometers is radiated substantially orthogonal to the feature 222 and layers surrounding the feature. In one embodiment, the endpoint detection system 480 is set to detect wavelengths between 700 and 800 nanometers, which are reflected off the polysilicon layer 206. More specifically, the endpoint detection system set to detect wavelengths of about 750 nm. As such, the endpoint detection system periodically measures the intensity of the particular wavelengths selected for measurement.

In particular, the polysilicon layer 206 has a refractive index of 4.0 to 4.6. For a radiated wavelength of 750 nm, a transmitted wavelength of 163 nm to 187.5 nm is produced, depending on the refractive index of the polysilicon. The filtering device 488 removes other reflected light at different wavelengths produced by other layers, such that the desired reflected light at a wavelength of 750 nm may be measured. The spectrometer 492 measures the intensity of the reflected light from the polysilicon layer 206. The measured intensity is compared to a previously determined intensity value, which is associated with the desired size of the undercut. The previously determined intensity value is determined by empirical data. If the measured intensity value is less than the predetermined intensity value, then the etching process continues. Once the measured intensity value and the predetermined intensity value are the same, the endpoint detection system 480 terminates the etch process.

In another embodiment, the change in intensity measurements during the etch process is used to determine the etch rate and predict the endpoint. In particular, the intensity of reflected light from the polysilicon layer 206, which has a wavelength of 750 nanometers, is selected for monitoring. Intensity readings for that particular wavelength is taken every 0.1 seconds to formulate an average etch rate. In one embodiment, for an undercut having diameters of 400 nm, the intensity measurements were taken approximately every 0.1 seconds.

The endpoint detection system 480 formulates the etch rate from the changes in intensities, terminates the etching process after 25 seconds to provide the desired undercut.

FIG. 6 depicts a graph 600 of an exemplary reflectivity trace during an isotropic etch process. The graph 600 comprises a y-axis 602 representing intensity magnitude, while an x-axis 604 represents time. The graph 600 further shows a curve 606 that has a negative slope, which represents that the intensity of the reflected light at the selected wavelength is decreasing. As discussed above, the intensity decreases as the material (e.g., polysilicon material 206) is removed, since there is less surface area available to reflect the light as the isotropic etch process progresses.

In one embodiment, the curve 606 may be used to examine the percent change in the intensity to predict when the critical dimension of the feature grows to a target value. In a second embodiment, the area under the curve 606 may be periodically integrated, such that when a target area under the curve 606 is reached, the endpoint detection system terminates the etch process.

Although various embodiments that incorporate the teachings of the present invention have been shown and described in detail herein, those skilled in the art can readily devise many other varied embodiments that still incorporate these teachings.

What is claimed is:

1. A method for controlling lateral etching during an etching process, comprising:
laterally etching a lower layer of a stack of layers;
radiating a spectrum of light over said lower layer being etched and an area over said stack of layers proximate to said lower layer being etched;
measuring intensity of light reflected from at least one of said stacked layers positioned lateral to said lower layer being etched; and
ceasing said etching process upon measuring a predetermined metric associated with said intensity of reflected light from said at least one of said stacked layers.

2. The method of claim 1, wherein said laterally etched lower layer is an undercut formed in said lower layer.

3. The method of claim 1, wherein said laterally etched lower layer forms a notched gate of a transistor.

4. The method of claims 1, wherein said etching process comprises an isotropic etching process.

5. The method of claim 1, wherein said radiating step further comprises:
providing a light source producing light having wavelengths in a range of about 200 nanometers to 800 nanometers.

6. The method of claim 1, wherein said radiating step further comprises:
radiating said light substantially perpendicular to said stack of layers.

7. The method of claim 1, wherein said measuring step further comprises:
measuring intensity changes of one or more wavelengths of light respectively reflected from one or more layers positioned lateral to said laterally etched lower layer.

8. The method of claim 7, wherein said measuring step further comprises:
detecting different wavelengths of reflected light;
selecting at least one of said wavelengths of detected light; and
measuring changes of intensity of said selected wavelengths of light over a period of time.

9. The method of claim 8, wherein said selecting at least one of said wavelengths of detected light further comprises filtering undesirable wavelengths of reflected light.

10. The method of claim 1, wherein said predetermined metric comprises a magnitude of intensity of light having a particular wavelength reflected from a particular layer of said stack of layers.

11. The method of claim 1, wherein said predetermined metric comprises a change of intensity over a period of time.

12. The method of claim 8, wherein said selecting step comprises:
identifying a wavelength of light that reflects from an upper surface of said lower layer and reflects from an upper surface of a sub-layer formed beneath said lower layer; and
monitoring in-phase intensity changes of said reflected light from said upper surface of said lower layer and said upper surface of a sub-layer formed beneath said lower layer.

13. The method of claim 8, wherein said selecting step comprises:
identifying a wavelength of light that reflects from an upper surface of said lower layer and reflects from an upper surface of a sub-layer formed beneath said lower layer; and
monitoring out-of-phase intensity changes of said reflected light from said upper surface of said lower layer and said upper surface of a sub-layer formed beneath said lower layer.

14. A method for controlling lateral etching of a notch in a transistor gate layer of a transistor during an etching process, said transistor comprising a stack of layers disposed below said transistor gate layer, said method comprising:
laterally etching a lower portion of said transistor gate layer;
radiating a selected wavelength of light over an upper surface of said transistor gate;
measuring intensity of light reflected from the upper surface of said transistor gate and a layer of said stack of layers positioned beneath said transistor gate; and
ceasing said etching process upon measuring a predetermined metric associated with said intensity of reflected light from said at least one of said stacked layers.

15. The method of claim 14, wherein said measuring step comprises measuring intensity of at least one wavelength that is in-phase light reflected from the upper surface of said transistor gate and the layer positioned beneath said transistor gate.

16. The method of claim 14, wherein prior to said laterally etching step, said method further comprises:
measuring intensity of light reflected from the upper surface of said transistor gate and the layer positioned beneath said transistor gate.

17. The method of claim 14, wherein said measuring step comprises measuring intensity of at least one wavelength that is out-of-phase light reflected from a transition area defined by an area of said transistor gate proximately said notch and a vacuum environment within said notch.

18. The method of claim 14, wherein said measuring step further comprises:
measuring intensity of light reflected from the upper surface of said transistor gate and the layer positioned beneath said transistor gate; and
measuring intensity of at least one wavelength that is out-of-phase light reflected from a transition area defined by an area of said transistor gate proximately said notch and a vacuum environment within said notch.

19. Apparatus for controlling lateral etching during an etching process, comprising:
means for laterally etching a lower layer of a stack of layers;
means for radiating a spectrum of light over said lower layer being etched and an area over said stack of layers proximate to said lower layer being etched;
means for measuring intensity of light reflected from at least one of said stacked layers positioned lateral to said lower layer being etched; and
means for ceasing said etching process upon measuring a predetermined metric associated with said intensity of reflected light from said at least one of said stacked layers.

20. The apparatus of claim 19, wherein said laterally etched lower layer is an undercut formed in said lower layer.

21. The apparatus of claim 19, wherein said laterally etched lower layer forms a notched gate of a transistor.

22. The apparatus of claims 19, wherein said etching process comprises an isotropic etching process.

23. The apparatus of claim 19, wherein said radiating means further comprises: providing a light source producing light having wavelengths in a range of about 200 nanometers to 800 nanometers.

24. The apparatus of claim 19, wherein said radiating means further comprises: radiating said light substantially perpendicular to said stack of layers.

25. The apparatus of claim 19, wherein said measuring means further comprises: measuring intensity changes of one or more wavelengths of light respectively reflected from one or more layers positioned lateral to said laterally etched lower layer.

26. The apparatus of claim 25, wherein said measuring means further comprises:
means for detecting different wavelengths of reflected light;
means for selecting at least one of said wavelengths of detected light; and
means for measuring changes of intensity of said selected wavelengths of light over a period of time.

27. The apparatus of claim 19, wherein said means for selecting at least one of said wavelengths of detected light comprises a filtering means for removing undesirable wavelengths of reflected light.

28. The apparatus of claim 19, wherein said predetermined metric comprises a magnitude of intensity of light having a particular wavelength reflected from a particular layer of said stack of layers.

29. The apparatus of claim 19, wherein said predetermined metric comprises a change of intensity over a period of time.

30. The apparatus of claim 26, wherein said selecting means comprises:
identifying a wavelength of light that reflects from an upper surface of said lower layer and reflects from an upper surface of a sub-layer formed beneath said lower layer; and
monitoring in-phase intensity changes of said reflected light from said upper surface of said lower layer and said upper surface of a sub-layer formed beneath said lower layer.

31. The apparatus of claim 26, wherein said selecting means comprises:
identifying a wavelength of light that reflects from an upper surface of said lower layer and reflects from an upper surface of a sub-layer formed beneath said lower layer; and
monitoring out-of-phase intensity changes of said reflected light from said upper surface of said lower layer and said upper surface of a sub-layer formed beneath said lower layer.
